(19) United States
(12) Patent Application Publication
(10) Pub. No.: US 2020/0161487 A1
(43) Pub. Date: May 21, 2020

(54) PHOTOVOLTAIC MODULE

(71) Applicant: Nederlandse Organisatie voor toegepast-natuurwetenschappelijk Onderzoek TNO, 's-Gravenhage (NL)

(72) Inventor: Evert Eugene Bende, Petten (NL)

(73) Assignee: Nederlandse Organisatie voor toegepast-natuurwetenschappelijk Onderzoek TNO, 's-Gravenhage (NL)

(21) Appl. No.: 16/631,843

(22) PCT Filed: Jul. 16, 2018
(86) PCT No.: PCT/NL2018/050493

§ 371 Date: Jan. 17, 2020

(30) Foreign Application Priority Data
Jul. 21, 2017 (NL) 2019318

(51) Int. Cl. H01L 31/048; H01L 31/05; H01L 31/054; H01L 31/18

(52) U.S. Cl. CPC H01L 31/048; H01L 31/18; H01L 31/054; H01L 31/05

(57) ABSTRACT

A photovoltaic module having one or more photovoltaic cells (2) positioned in a space between a front sheet (4) and a back sheet (5), the space being filled with an encapsulant material (6). The photovoltaic module (1) has a plurality of ribbons (3) providing an electrical interconnection of the one or more photovoltaic cells (2). A single visible-light absorbing layer (7) is present having a pattern which includes partial areas aligned with the plurality of ribbons (3). The partial areas have a width (w+e) which is equal to a width (w) of the associated ribbon (3) plus a symmetrically applied extension width (e). The extension width (e) and height (h) are determined according to the equation:

$$\frac{2 h}{w + e} < tan ( 90 - {sin}^{- 1} ( 1 \text{/} {n}_{E} ) )$$

wherein n_{E} is the refractive index of the encapsulant material (6). The single visible-light absorbing layer (7) is provided on an internal face of the front sheet (4).

### FIELD OF THE INVENTION

The present invention relates to a photovoltaic module having a one or more photovoltaic cells, the one or more of photovoltaic cells being positioned in a space between a front sheet and a back sheet, the space further comprising an encapsulant material, the photovoltaic module comprising a plurality of ribbons, the plurality of ribbons providing an electrical interconnection of the one or more photovoltaic cells.

### BACKGROUND ART

A photovoltaic (PV) module known in the art comprises active regions which are the photosensitive portions of the individual cells, inactive regions which comprise most of the other portions of the module (such as framing and marginal regions in and around the array of cells) and semi-active regions (such as metal interconnects and back sheet areas close to the cells) which are able to redirect a portion of incident light onto active areas by (double) reflection. The visual appearance of a PV module is determined by these features, with the active areas appearing relatively dark (very dark if the majority of incident light is absorbed) and metallic areas appearing relatively bright. Visible portions of the back sheet depend on the material of the back sheet, which could be transparent (particularly if the back sheet is a glass back sheet), white (for maximum module efficiency), or black (if an overall dark appearance is desired). Currently all-black modules that are for sales in the market have a black back sheet and black frames. However the metallized regions remain relatively bright which is aesthetically less appealing than if one would have a homogeneous black surface.

US patent publication US2012/0247541 discloses a coloured photovoltaic (PV) module comprising a photovoltaic cell and an appearance modifying system that interacts with at least a portion of the incident light on the photovoltaic cell to cause a modified visual appearance to an observer. The appearance modifying system spatially demultiplexes incident light to provide a power-creating component and an appearance-modifying component. The appearance-modifying component is substantially directed to the observer, and comprises in an embodiment a plurality of facets provided to a glazing layer and embedded elements provided to photovoltaically inactive areas. The spatially demultiplexing comprises configuring the facets and embedded elements such that the facets refract light reflecting off the embedded elements substantially toward the observer.

US patent publication US2008/0006323 discloses a photovoltaic module with an encapsulated photovoltaic element and an infrared transmissive decorative overlay. It will be clear that the infrared transmissive decorative overlay will have a negative effect on the performance of the photovoltaic module, as also active regions are adversely affected by the scattering effect caused by the overlay with a light diffusion function.

US patent publication US2009/0151771 discloses an interferometric mask covering a reflective conductive ribbon that electrically interconnects a plurality of photovoltaic cells. Such an interferometric mask may reduce reflections of incident light from the conductors. In various embodiments, the mask reduces reflections, so that a front and back electrode pattern appears black or similar in color to surrounding features of the device. In other embodiments, the mask may modulate reflections of light such that the electrode pattern matches a color in the visible spectrum. Disadvantage is that such a construction of the ribbons is difficult to manufacture and hard to solder on the busbars. Heat transfer is hampered by the optical resonance cavity.

Chinese patent publication CN-A-102623554 discloses a method for manufacturing a solar cell module, which comprises a procedure of manufacturing solar cells wherein conventional silver welding strips are substituted by black or dark gray welding strips. The method is low in cost and suitable for large-scale production. Disadvantage is that the heat transfer of the soldering process is hampered by the inorganic pigments used. This makes the soldering unreliable and causes a brittle junction between busbar and ribbon, thereby adversely affecting the long-term reliability of modules in outdoor conditions during the lifetime of over 25 years.

### SUMMARY OF THE INVENTION

The present invention seeks to provide a photovoltaic module which has good performance in aesthetic sense. The present invention allows soldering of conventional Tin-coated copper ribbons and enables a substantially complete black appearance of the module.

According to the present invention, a photovoltaic module as defined above is provided, further comprising a single visible-light absorbing layer having a pattern which at least includes partial areas aligned with the plurality of ribbons, wherein the partial areas aligned with the plurality of ribbons have a width w+e which is equal to a ribbon width w of the associated plurality of ribbons plus a symmetrically applied extension width e, wherein a height h is present between a front surface of the plurality of ribbons 3 and the single visible-light absorbing layer 7, wherein the extension width e and height h are determined according to the equation:

$$\frac{2 h}{w + e} < tan ( 90 - {sin}^{- 1} ( 1 \text{/} {n}_{E} ) )$$

wherein n_{E} is the refractive index of the encapsulant material, and wherein the single visible-light absorbing layer is provided on an internal face of the front sheet.

In combination these features ensure that the appearance of the photovoltaic module is entirely dark (black) for an observer.

### SHORT DESCRIPTION OF DRAWINGS

The present invention will be discussed in more detail below, with reference to the attached drawings, in which

FIG. 1 shows a frontal view of a photovoltaic module;

FIG. 2 shows a perspective view of a photovoltaic module according to a further embodiment of the present invention;

FIG. 3 shows a top view of an embodiment of a single visible-light absorbing layer as applied in the present invention photovoltaic module embodiments;

FIG. 4 shows a partial cross sectional view of a photovoltaic module according to an embodiment of the present invention,

FIG. 5 shows a partial cross sectional view of a photovoltaic module illustrating isotropic reflection, and

FIGS. 6A and 6B show partial cross sectional views of two further embodiments of the present invention photovoltaic module.

### DESCRIPTION OF EMBODIMENTS

Photovoltaic modules having one or more photovoltaic cells are widely used nowadays, and the further integration in buildings and living areas continues to drive efforts to obtain more efficient photovoltaic modules, but also to obtain photovoltaic modules having a more aesthetic appearance.

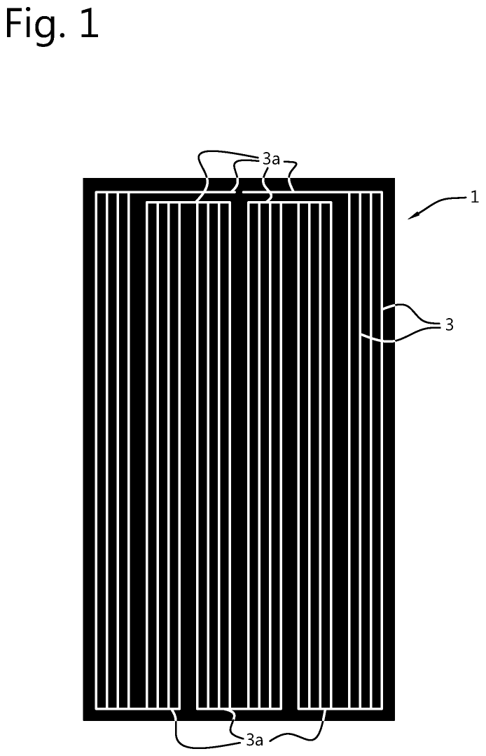

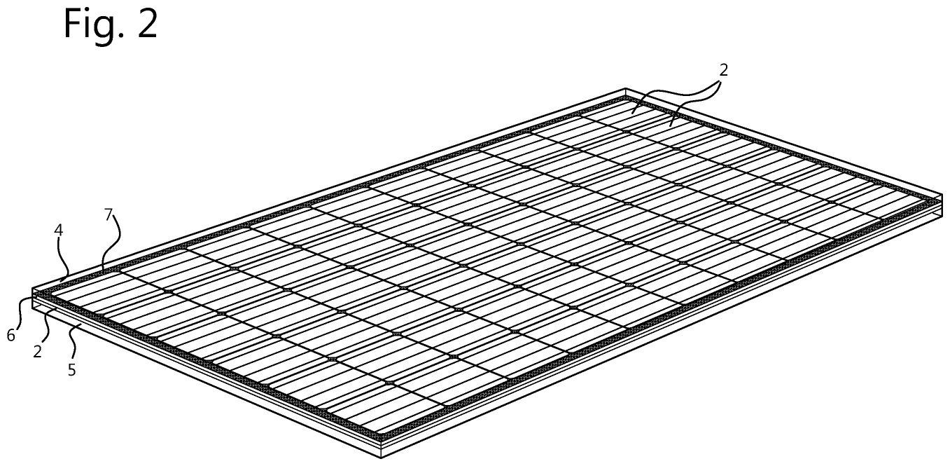

In FIG. 1 a frontal view is shown of a photovoltaic (PV) module 1, in what is known in the field as an ‘all-black’ PV module. The appearance of the PV module 1 is almost entirely dark, with the exception of ribbons 3 interconnecting individual photovoltaic cells 2 of the photovoltaic module 1 (see embodiment described with reference to FIG. 2 below), and bussings 3a, interconnecting ends (or terminals) of ribbons 3. In general the bussings 3a extend in a direction perpendicular to the direction of the ribbons 3. The ribbons 3 and bussings 3a in this particular PV module 1 version are made of conducting material, and in general are made of a material reflecting visual radiation (light), usually implemented as a tinned flat copper wire. So even in the case of an ‘all-black’ PV module 1, the appearance of the PV module 1 is still not entirely black.

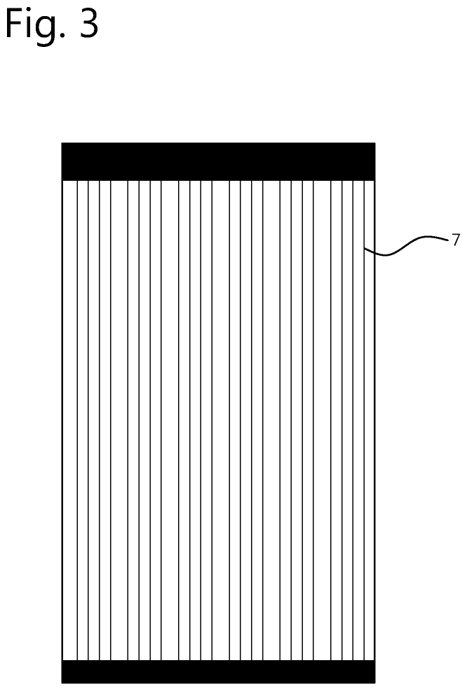

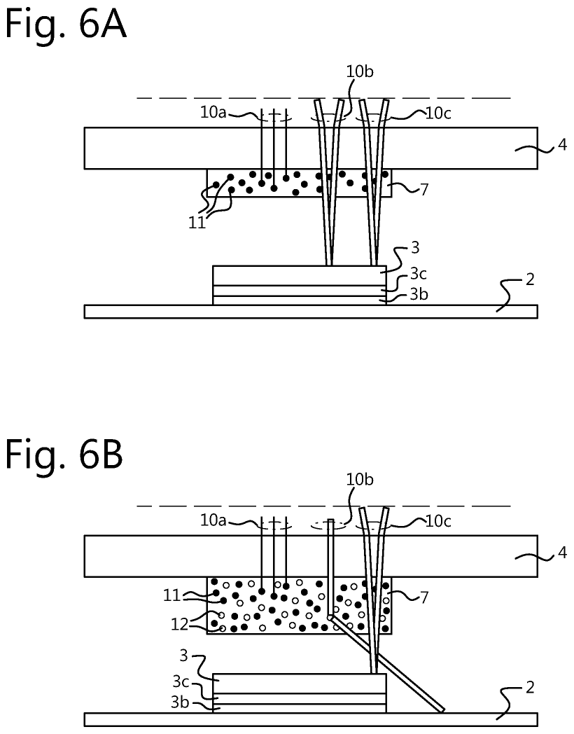

In FIG. 2 a perspective view is shown of a further variant of a PV module 1, in this case having a 6×10 array of photovoltaic cells 2 (see also the description of FIG. 3 below). Visible in this perspective view is the usual layered structure of a photovoltaic module 1, comprising (from bottom to top) a back sheet 5, an encapsulant layer comprising an encapsulant material 6 wherein the photovoltaic cells 2 are embedded, and a (glass) front sheet 4. Each photovoltaic cell 2 is provided with busbars 3b on top for collecting charge carriers from the photovoltaic cell 2, as well as with ribbons 3 (or tabs) which interconnect adjacent ones of the plurality of photovoltaic cells 2. In general the ribbons 3 are connected to the busbars 3b using soldering connections/layers 3c (see also the embodiments shown in FIGS. 6A and 6B, which are described in more detail below). Also shown in the perspective view of FIG. 2 is a single visible-light absorbing layer 7, which according to an embodiment of the invention, is applied to a back surface of the front sheet 4 of the photovoltaic module 1. The single visible-light absorbing layer 7, with the further features as discussed in more detail below, will effectively mask the otherwise reflecting (and thus visible) parts of the photovoltaic module 1, in particular the ribbons 3 and bussings 3a as shown in FIG. 1. It is noted that in actual implementations, the stack of layers may comprise even further layers, such as an anti-reflection coating (ARC) layer (e.g. on top of the front sheet 4).

In this description, visible light is defined as radiation which is visible to the human eye, which in general corresponds to a wavelength region of 390-700 nm. Also relevant for photovoltaic modules 1 can be near infrared radiation (substantially with a wavelength region of 700-1000 nm), as (part of) this radiation can be converted by the photovoltaic cells 2. Furthermore, infrared radiation may impinge on the photovoltaic module 1, substantially with a wavelength region of more than 1000 nm.

For the exemplary embodiment of the PV module 1 as shown in FIG. 1, the ribbons 3, bussings 3a and photovoltaic cell(s) 2 are embedded in the encapsulant layer 6 between the front sheet 4 and back sheet 5. The single visible-light absorbing layer 7 in this embodiment is applied in alignment with areas above the ribbons 3 and bussings 3a (e.g. as a layer 7 against the top sheet 4). The single visible-light absorbing layer 7 will then have the shape as shown in the top view of FIG. 3. It is noted that the specific embodiment of the single visible-light absorbing layer 7 as shown in FIG. 3 may also be applied to the 6×10 array embodiment as shown in FIG. 2, wherein the areas of the single visible-light absorbing layer 7 are then aligned with the ribbons 3 which are present on top of and between each photovoltaic cell 2 (e.g. in the form of four parallel lines as shown in the embodiment of FIG. 2), as well as aligned with further (non-active) areas of the photovoltaic module 1, such as spaces between individual photovoltaic cells 2, or areas at the perimeter of the photovoltaic module 1. The application of the single visible-light absorbing layer 7 will provide the PV module 1 with a real dark appearance.

In the embodiment shown, the single visible-light absorbing layer 7 has a pattern which at least includes areas in alignment with the ribbons 3 (and bussings 3a) of the photovoltaic module 1. In the exemplary embodiment of FIG. 2, the pattern of the visible-light absorbing layer 7 is aligned with the plurality of (optically reflecting) ribbons 3 on the radiation receiving areas of each of the photovoltaic cells 2 (the four parallel lines above each photovoltaic cell 2), as well as with the areas between individual photovoltaic cells 2 where the ribbons 3 are positioned, and the area of the photovoltaic module forming an outside perimeter of the photovoltaic module 1. In further embodiments the present invention may be implemented in various kinds of photovoltaic modules, e.g. comprising a 6×12 array of photovoltaic cells 2, comprising a plurality of poly-crystalline photovoltaic cells 2 (which can be rectangular as opposed to mono-crystalline photovoltaic cells 2 which normally have rounded edges due to the shape of the single ingot silicon crystal from which these are produced), or comprising one or more thin film photovoltaic cells 2.

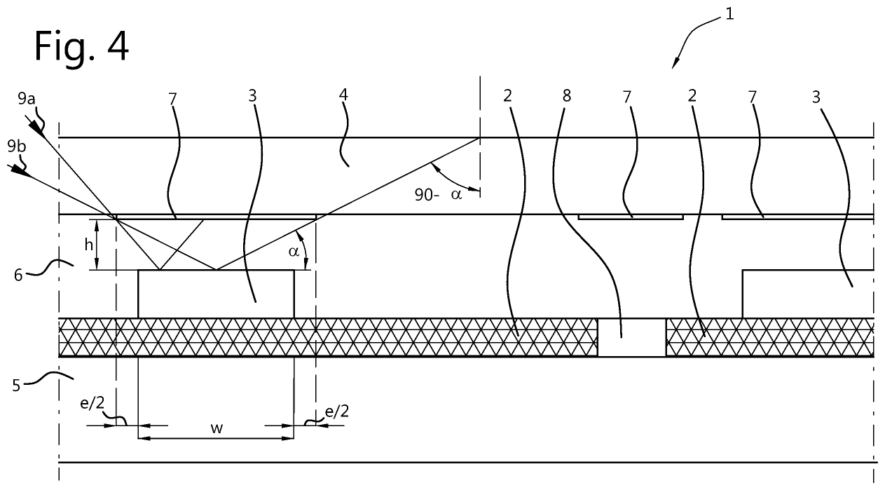

The present invention embodiments will be further explained with reference to the partial cross-sectional view of a photovoltaic module 1 as shown in FIG. 4. In the cross sectional view of the FIG. 4 embodiment, two photovoltaic cells 2 are partially shown, which in the photovoltaic cell layer are separated by an inter-cell gap 8. In general wording, the one or more photovoltaic cells 2 of the photovoltaic module 1 are positioned in a (sealed) space between a front (glass) sheet 4 and a back sheet 5, wherein the space comprises an encapsulant material 6. The photovoltaic module 1 comprises a plurality of (optically reflecting) busbars and ribbons 3. When using silicon based photovoltaic cells 2, the ribbons 3 are applied to all metallic electrode material on the front side, e.g. gridline electrodes, bus electrodes and pads, busbars, etc. positioned (directly) on a main radiation receiving surface of the one or more photovoltaic cells 2, and also the ribbons 3 interconnecting adjacent photovoltaic cells 2 are generally of metallic electrode material, and are thus reflecting light (visible radiation). In exemplary implementations, each photovoltaic cell 2 may comprise three, four (as shown in the embodiment of FIG. 2), five or even six (usually parallel) busbars, or the busbars may comprise a complex electrode pattern. In case of a thin film photovoltaic cell, the busbars may even comprise a large number of (parallel) busbars running along the length of the photovoltaic module 1. In addition, the ribbons 3 may also be present covering all busbars, interconnecting the one or more photovoltaic cells 2 with each other (in parallel and/or series circuit connection).

Furthermore, according to the present invention embodiments, a single visible-light absorbing layer 7 is provided, having a pattern which at least includes areas aligned with the plurality of ribbons 3.

The single visible-light absorbing layer 7 may be arranged to absorb radiation impinging on a front surface of the photovoltaic module 1. According to any one of the present invention embodiments, the pattern of the visible-light absorbing layer 7 at least includes partial (e.g. rectangular) areas aligned with the plurality of ribbons 3. In a further embodiment, the pattern of the visible-light absorbing layer 7 further includes further partial areas aligned with conducting bussings 3a of each of the one or more photovoltaic cells 2. It is noted that the further partial areas may individually be stretching over the area covered by multiple bussings 3a, including spaces between bussings 3a, as shown in the embodiments of FIG. 3 (see bussings 3a in FIG. 1).

In the cross-sectional view of FIG. 4, two impinging light rays 9a, 9b are shown which would e.g. represent light impinging on the front surface of the photovoltaic module 1 from different directions. The steeper ray 9a would specularly reflect on the (reflecting) surface of the ribbon 3, and impinges on a back side of the single visible-light absorbing layer 7. In case the single visible-light absorbing layer 7 is a fully absorbing layer (e.g. black), the ray 9a would then be absorbed. For the ray 9b which impinges under a more shallow angle just along a width of the single visible-light absorbing layer 7 the ray 9b would just be able to be reflected from the surface of the ribbon 3 at an angle α as indicated, and proceed into the encapsulant layer 6 and to the front sheet 4. As the breaking index of regular encapsulant material (e.g. EVA) is very near to the refractive index of the material of the front sheet 4 (e.g. glass), the ray 9b will finally refract and reflect at the glass air interface as indicated (and remain within the photovoltaic module 1 for this specific angle α). The refraction will depend on the height h of the encapsulant layer 6 above the ribbon 3, but also on the (local) width of the single visible-light absorbing layer 7. At the indicated angle α, the ray 9b of the refracted light beam leaves the PV module 1 parallel at the surface of the PV module 1. Beyond the indicated angle Total Internal Reflection (TIR) takes place, and then the light beams stays inside the PV module 1 and is hence not visible to an observer.

This effect may be exploited to make the photovoltaic module 1 appear more aesthetically pleasing. The ribbons 3 (and bussings 3a) tend to reflect radiation entering the photovoltaic module 1 in a specular way. Light can enter the photovoltaic module 1 under an angle, subsequently reflect at the ribbon 3 and then leave the photovoltaic module 1 provided that the angle of the light beam with the normal at the air-glass surface (top of front sheet 4) is smaller than the critical angle α (i.e. sin⁻¹ (1/n)=42° for the refractive index being n=1.5), where n is the refractive index of glass (i.e. the material of the front sheet 4). If the light beam 9b hits the surface at a greater angle the light will not be able to escape from the photovoltaic module 1 and thus will not hit the eyes of an observer. This implies that the ribbons 3 are invisible. As shown with reference to FIG. 4 for the rays 9a, 9b, the criterion of non-visibility of a specular reflecting ribbon 3 for the ratio of the distance h between top surface of ribbon 3 and front sheet 4, and the width w of the ribbon 3 can be determined. If the angle α is smaller than 90−sin⁻¹(1/n_{E}) the light cannot escape from the photovoltaic module 1 and is thus subject to Total Internal Reflection (TIR). The smallest angle for light to be reflected back at the specular reflecting ribbon 3 obeys the equation tan(α)=h/(w/2), where h is the distance between the single visible-light absorbing layer 7 (e.g. in the form of a black stripe on the front sheet 4) and the ribbon 3, and where w is the width of the ribbon 3. If the angle α under which light is reflected is larger than tan⁻¹(h/(w/2)) the light impinges the single visible-light absorbing layer 7 and is therefore being absorbed. If the angle is smaller than 90−sin⁻¹(1/n) it will not leave the photovoltaic module 1. So the criterion for which light cannot escape the photovoltaic module 1 is given by h/(w/2)<tan(90−sin⁻¹ (1/n)).

In an example, tan(90−sin⁻¹(1/n))=tan(90−sin⁻¹(1/1.5))=1.11 and the ribbon 3 has a width of w=1000 μm. If an encapsulant (EVA) layer 6 thickness of 500 μm is chosen in combination with a thickness of ribbon 3 of 200 μm, the distance h between layer 7 and ribbon 3 becomes 300 μm. Since then h/(w/2)=0.6 it smaller than 1.11 and therefore no light, specularly reflected at the ribbon 3, can escape the photovoltaic module 1.

In one embodiment, the areas (of the single radiation layer 7) aligned with the plurality of ribbons 3 have a pattern width (w+e) which is equal to a ribbon width (w) of the associated plurality of ribbons 3 plus a symmetrically applied extension width (e), as shown in FIG. 2 (i.e. the single visible-light absorbing layer 7 thus extends over a distance e/2 on either side). The extension width (e) is selected according to the equation:

$$\frac{2 h}{w + e} < tan ( 90 - {sin}^{- 1} ( 1 \text{/} {n}_{E} ) )$$

wherein n_{E} is the refractive index of the encapsulant material 6, and h is a height between a front surface of the plurality of ribbons 3 and the single visible-light absorbing layer 7. This embodiment describes an invisibility criterion for specular reflected light, and as a surprising effect, it is not dependent on the refractive index of the front sheet 4 (glass) or on the refractive index of an Anti Reflection Coating on top of the front sheet 4.

In a further embodiment, the extension width (e) is determined according to the equation:

$$\frac{2 h}{e} < tan ( 90 - {sin}^{- 1} ( 1 \text{/} {n}_{E} ) )$$

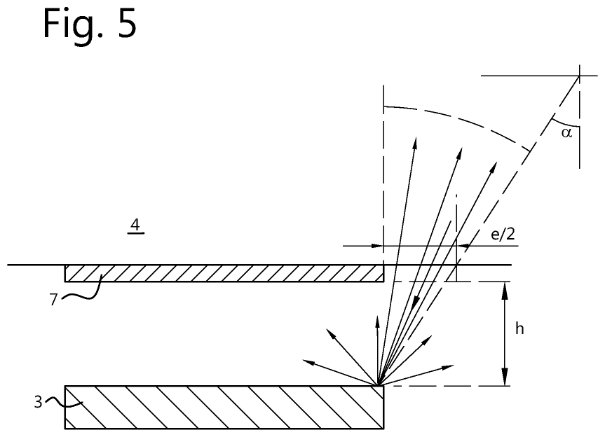

The metal ribbons 3 are to a high degree specular reflecting bodies, however a small part of the light may be reflected in an isotropic sense, as shown in the cross sectional view of a further embodiment in FIG. 5. In this case, the invisibility criterion is applied for isotropically scattered light at (an end part) of the ribbon 3 (e.g. when a ribbon 3 is provided with a coating). This requirement is more stringent in order that scattered light at an edge of the ribbon 3 is limited by the overlying single visible-light absorbing layer 7. It is to be noted that this criterion is independent of the width w of ribbon 3.

In a further exemplary embodiment, the pattern width (w+e) is at least 50 μm larger than the ribbon width (w), e.g. 100 μm larger. If the single visible-light absorbing layer 7 is e.g. a black strip, this will ensure that the ribbon 3 Is not visible from the front side of the photovoltaic module 1.

Referring back to FIG. 2, according to a group of the present invention embodiments, the pattern of the single visible-light absorbing layer 7) further include areas outside of radiation receiving main surfaces of the one or more photovoltaic cells 2. In one group of embodiments, the pattern further includes areas aligned with spaces between adjacent ones of the one or more photovoltaic cells 2, and in a further group of embodiments the pattern further includes areas aligned with spaces outside of a perimeter of the one or more photovoltaic cells 2. In other words, also the metal areas in between cells and the non-metallized areas between photovoltaic cells 2, and possible even further also the areas at the edges of the photovoltaic module 1 are part of the alignment of the single visible-light absorbing layer 7. Also for these parts the above embodiments may be applied with respect to an associated extension width e. In areas where layer 7 does not shield active radiation-absorbing photovoltaics cells the extension e may be bigger than is required based on the invisibility criterions. In these areas layer 7 might also cover more than one bussing or ribbons. In this way a more homogeneous appearance can be realized.

The extension e might also be chosen bigger than required on the basis of the invisibility criterion for specularly reflected light or for isotropically scattered light, since a certain tolerance is needed in the manufacturing process to align the ribbons 3 and bussings 3a with the pattern of layer 7.

As shown more clearly in the cross sectional view of FIG. 2, but also apparent from the perspective view of FIG. 1, the single visible-light absorbing layer 7 is provided on an internal face of the front sheet 4. In relation to the thickness of the encapsulant layer 6 and the thickness of the ribbon 3, the single visible-light absorbing layer 7 is relatively thin, and may be applied easily to the front sheet 4, still maintaining an efficient shielding function as intended.

In a group of embodiments, the the back sheet 5 is a transparent back sheet and the photovoltaic module 1 comprises a secondary single visible-light absorbing layer 7 provided on an internal face of the back sheet 5, i.e. facing the ribbons 3 and photovoltaic cells 2 at a close distance on the back side of the photovoltaic module 1. The photovoltaic module 1 can in this group be a monofacial module or a bifacial module. Bifacial photovoltaic modules 1 may have a higher efficiency as radiation can impinge on both sides of the photovoltaic cells 2, and because of the transparency of both the front sheet 4 and back sheet 5 may also have a nice appearance. Such photovoltaic modules 1 with bifacial cells 2 can e.g. find their application in the field of commercial scale PV power plants and on flat roofs where systems can utilize the albedo effect of roof reflection, e.g. on factory roofs.

The single visible-light absorbing layer 7 (and the optional secondary single visible-light absorbing layer 7) is a visible-light absorbing layer for a specific wavelength range in a further group of embodiments, e.g. a black or pigmented layer, as will be discussed in more detail below. In even further alternative embodiments, the single visible-light absorbing layer 7 (and the optional secondary single visible-light absorbing layer 7) comprises a scattering layer. This can be implemented as a separate layer, or as an additional feature of the single visible-light absorbing layer 7.

The present invention may thus be implemented in a large number of photovoltaic module 1 variants. A first version is where the single visible-light absorbing layer 7 is implemented as a black layer in a photovoltaic module 1. The photovoltaic module 1 in one embodiment has a glass front sheet 4 and a black back sheet 5, wherein the black layer 7 is applied to (printed on) the front sheet 4 (all-black module). The invisibility criterion here ensures that all the ribbons 3 will remain invisible for the observer. However, a black layer 7 may also be implemented in a photovoltaic module 1 having both a transparent (e.g. glass) front sheet 4 and a transparent (e.g. glass) back sheet 5, in combination with mono-facial photovoltaic cells 2.

In a group of embodiments, the back sheet 5 is a glass sheet. Alternatively, the back sheet 5 is a polymer sheet, in a further group of embodiments. In both alternatives, the back sheet 5 may be provided with a visible-light absorbing layer, e.g. as a black (polymer) back sheet.

A further group of embodiments relates to the selection of the material of the single visible-light absorbing layer 7. The single visible-light absorbing layer 7 may comprise an absorbing material selected from the group of: an ink material, a screen print material (e.g. a paste), or an inorganic material. In a further embodiment, the back sheet 5 also comprises the absorbing material, which would provide a similar color impression of the entire PV module 1 for an observer. In order to match the appearance of the masking single visible-light absorbing layer 7 and the rest of the PV module 1, in a further embodiment, the absorbing material comprises a black pigment, a brown or brownish pigment, a red or redish pigment, or a blue or blueish pigment.

The black pigments can be one of, or a combination of:

Acetylene Black; Aniline Black; Antimony Black; Asphaltum; Black Earth; Black Hematite; Black Tourmaline; Bone Black; Carbon Black; Chrome Iron Nickel Black; Chromium Green Black Hematite; Cobalt Black; Cobalt Nickel Gray; Cobaltic Oxide; Copper Chromite Black; Copper Chromite Black; Cuprous Sulfide; Graphite; Hartshorn Black; Iron Cobalt Black; Iron Cobalt Chromite Black; Iron Manganese Oxide; Iron Titanium Brown Spinel; Ivory Black; Lamp black; Lead Sulphide; Logwood; Logwood; Logwood Black Lake; Logwood Lake; Magnetite; Manganese Black; Manganese Ferrite Black; Mars Black; Micaceous Iron Oxide; Mineral Black; Mineral Black; Molybdenum Disulfide; Paliogen Black; Perylene Black; Pyrolusite; Shungite; Slate Black; Tin Antimony Gray; Titanium Dioxide Black; Titanium Vanadium Antimony Gray; Vine Black; Zinc Sulfide.

The blueish pigment is e.g. Phthalocyanine Blue, the redish pigment is e.g. a red iron oxide pigment, and the brownish pigment can be chrome iron oxide.

Examples of IR reflecting pigments in a paint, which are reflective in the wavelength range of 700-2500 nm are described in European patent publication EP-A-2525011, which is incorporated herein by reference.

FIG. 6A shows an exemplary embodiment of part of a photovoltaic module 1 focusing on the features of the present invention embodiments. The top part of a photovoltaic cell 2 is shown, onto which a busbar 3b is present. A ribbon 3 as applied over the busbar 3 using a soldering layer 3c. On top of the layer of encapsulant material 6, which surrounds the stack of busbar 3b, soldering layer 3c and ribbon 3, the top sheet 4 is present, and aligned with the ribbon 3 the single visible-light absorbing layer 7. The visible-light absorbing layer 7 is provided with pigment particles 11 forming the absorbing material as discussed above. Also drawn are three types of impinging light, of which the visible wavelength rays 10a are absorbed by the pigment particles 11. The composition and dimensions of the pigment particles 11 are such that rays 10b in the near IR wavelength region and rays 10c in the IR wavelength region are not affected, and transverse the visible-light absorbing layer 7. So in a specific embodiment, the visible-light absorbing material (of the visible-light absorbing layer 7) is transparent for near infrared and infrared radiation.

By properly selecting the composition and dimensions of the pigment particles 11, further embodiments may be envisaged, e.g. wherein the visible-light absorbing material is deflecting near infrared and/or infrared radiation. The deflection mechanism may be due to reflection, scattering or other optical effect of the pigment particles 11.

To obtain the effect as described, the single visible-light absorbing layer 7 further comprises a near infrared and/or infrared radiation scattering material. The near infrared or infrared radiation scattering material may be mixed with the absorbing material as discussed above (i.e. both in the single layer 7) or the two materials may be separated in specific sublayers. An example of the near infrared and/or infrared radiation scattering material comprises a TiO₂ based pigment, wherein the exact characteristics such as composition and particle dimensions and shapes may be exploited to obtain a desired effect on the (near) infrared radiation. E.g. the absorbing material might further comprise inorganic particles such as TiO₂ pigments that scatter light and that can enhance the optical path length in the absorbing material and thus enhances the absorption. Other examples of scattering pigments are Al2O3 or ZnO.

E.g., in a further embodiment the single visible-light absorbing layer 7 might comprise a ‘black’ pigment that only absorbs in the visible-light wavelength range. The pigment might be chosen such that it either reflects (N)IR light or is transparent to (N)IR light. In the former case the (N)IR light will be partly scattered out of the photovoltaic module 1 and is partly deflected so that (N)IR light may end up in the photovoltaic cells 2. The advantage is that NIR light will be converted to power by the (silicon) photovoltaic cell 2 whereas the IR light will undergo parasitic absorption and leads to undesired heating up of the photovoltaic module 1. In the latter case the (N)IR light will traverse layer 7 and will be reflected on the ribbon 3 and will then escape from the photovoltaic module 1. The advantage is that the undesired IR light will be reflected out of the module but the drawback is that this also hold for NIR which could otherwise contribute to power conversion.

In a further exemplary embodiment the single visible-light absorbing layer 7 has two sublayers, wherein one layer is provided with the pigment particles 11 as described above, and a second sublayer is provided with particles 12 optically deflecting near infrared radiation only. In a more general sense, the near infrared and/or infrared radiation scattering material is provided in a scattering layer below the visible-light absorbing layer 7.

In the embodiment shown in FIG. 6B, the visible-light absorbing layer 7 includes both the two types of particles 11, 12, which specific advantageous effects. First, the entire photovoltaic module 1 now appears visually black by absorbing visible light with a wavelength between 390 nm and 700 nm to meet the objective of aesthetics, as indicated for the rays 10a. Secondly, light with a wavelength between 700 nm and 1000 nm (near infrared) is scattered or deflected such that it will, possibly after a couple of internal reflections at e.g. the top sheet 4 interface, will end-up in the active region of the photovoltaic cell 2, as indicated for the rays 10b. Thirdly, light with wavelengths beyond approximately 1000 nm (infrared) will be reflected out of the module (as the top sheet 4 and layer 7 are transparent for this range of wavelengths, thereby preventing parasitic absorption causing undesired heating-up of the photovoltaic module 1 which would reduce the power output. It should be noted that in this exemplary embodiment the visually appearing entirely black photovoltaic module 1 can have a higher power output than the conventional one without layer 7.

In a further embodiment the absorbing material comprises TiO2 pigments that are relatively big, i.e. with diameters between 1000-3000 nm (or agglomerated small particles with the same effective size), that are relatively strong in scattering the (N)IR light. In this case (N)IR light might be coupled into the solar cells by deflection followed by absorption in the (silicon) solar cell, or subsequent deflection, reflection at the ribbon, reflection at the glass-air interface followed by absorption into the (silicon) solar cell.

In a further embodiment he ratio of the concentration in layer 7 of the TiO2 pigments and black pigment is chosen as x:1, where x<2 ensuring that the optical appearance is still black.

In a further embodiment layer 7 comprises a stack of layer. The first layer, adjacent to the top cover glass, having a visible-light absorbing pigments but transparent to (N)IR and a second layer with (TiO2) scattering pigments.

In a further embodiment this second layer has small (e.g. diameter <300 nm) pigments (like TiO2) for which a strong discrimination in scattering power between NIR and IR light exists. (See also the disclosure of PCT patent publication WO2013/066545, which is incorporated herein by reference). Then the scattering power is stronger for NIR than for IR light. This causes that NIR is more strongly deflected and/or reflected than IR light. By choosing a sufficiently low concentration of TiO2 pigments, NIR has a high chance of absorption into the solar cell since the following trajectories have a relatively high probability: deflection followed by absorption into the (silicon) solar cell, or subsequent deflection, reflection at the ribbon, reflection at the glass-air interface followed by absorption into the (silicon) solar cell. On the other hand, IR light is less strongly deflected and/or reflected, implying that the second layer is to great extent transparent for IR light. This implies that IR light has a high chance that it will be reflected at the ribbon and will escape the module, thereby preventing adverse heating up of the module.

In the description above, the embodiments are referred to as having one or more photovoltaic cells 2. These photovoltaic cells 2 may comprise one of the group of: thin film cells, mono crystalline cells or poly crystalline cells.

In a further aspect, the present invention embodiments relate to a method of manufacturing a photovoltaic cell according to any one of the (exemplary) embodiments described above, wherein the single visible-light absorbing layer 7 is applied to the front sheet 4 before assembly of the photovoltaic module 1. The single visible-light absorbing layer 7 is applied in further embodiment using one of the following application techniques: ink-jet printing, screen printing/stencilling, roller printing, tampon printing, pad printing, powder coating, laser sintering, thermal printing. It is noted that for bifacial embodiments of the photovoltaic module 1, also the secondary single visible-light absorbing layer may be applied in the same manner.

The present invention has been described above with reference to a number of exemplary embodiments as shown in the drawings. Modifications and alternative implementations of some parts or elements are possible, and are included in the scope of protection as defined in the appended claims.

1. A photovoltaic module having one or more photovoltaic cells,
the one or more of photovoltaic cells being positioned in a space between a front sheet and a back sheet, the space further comprising an encapsulant material,
the photovoltaic module comprising a plurality of ribbons, the plurality of ribbons providing an electrical interconnection of the one or more photovoltaic cells, and
a single visible-light absorbing layer having a pattern which at least includes partial areas aligned with the plurality of ribbons,
wherein the partial areas aligned with the plurality of ribbons have a width (w+e) which is equal to a ribbon width (w) of the associated plurality of ribbons plus a symmetrically applied extension width (e),
wherein a height (h) is present between a front surface of the plurality of ribbons and the single visible-light absorbing layer,
wherein the extension width (e) and height (h) are determined according to the equation:
$$\frac{2 h}{w + e} < tan ( 90 - {sin}^{- 1} ( 1 \text{/} {n}_{E} ) )$$
wherein n_{E} is the refractive index of the encapsulant material, and
wherein the single visible-light absorbing layer is provided on an internal face of the front sheet.

2. The photovoltaic module of claim 1, wherein the extension width (e) and height (h) are determined according to the equation:
$$\frac{2 h}{e} < tan ( 90 - {sin}^{- 1} ( 1 \text{/} {n}_{E} ) ) .$$

3. The photovoltaic module according to claim 1, wherein the width (w+e) of the partial areas aligned with the plurality of ribbons is at least 50 μm larger than the ribbon width (w).

4. The photovoltaic module according to claim 1, wherein the pattern of the single visible-light absorbing layer includes further partial areas aligned with conducting bussings of the photovoltaic module.

5. The photovoltaic module according to claim 1, wherein the pattern of the single visible-light absorbing layer further includes areas aligned with spaces between adjacent ones of the one or more photovoltaic cells.

6. The photovoltaic module according to claim 1, wherein the pattern of the single visible-light absorbing layer further includes areas aligned with spaces outside of a perimeter of the one or more photovoltaic cells.

7. The photovoltaic module according to claim 1, wherein the back sheet is a transparent back sheet, and the photovoltaic module comprises a secondary single visible-light absorbing layer provided on an internal face of the transparent back sheet.

8. The photovoltaic module according to claim 1, wherein the back sheet is a glass sheet.

9. The photovoltaic module according to claim 1, wherein the back sheet is a polymer sheet.

10. The photovoltaic module according to claim 8, wherein the back sheet is provided with a visible-light absorbing layer.

11. The photovoltaic module according to claim 1, wherein the single visible-light absorbing layer comprises an absorbing material selected from the group of: an ink material, a screen print material, an inorganic material.

12. The photovoltaic module according to claim 11, wherein the back sheet also comprises the absorbing material.

13. The photovoltaic module according to claim 11, wherein the visible-light absorbing material comprises a black pigment, a brownish pigment, a redish pigment, a blueish pigment.

14. The photovoltaic module according to claim 11, wherein the visible-light absorbing material is transparent for near infrared and infrared radiation.

15. The photovoltaic module according to claim 11, wherein the visible-light absorbing material is deflecting near infrared and/or infrared radiation.

16. The photovoltaic module according to claim 1, wherein the single visible-light absorbing layer further comprises a near infrared and/or infrared radiation scattering material.

17. The photovoltaic module according to claim 1, wherein the one or more photovoltaic cells comprise one of the group of: thin film cells, mono crystalline cells or poly crystalline cells.

18. A method of manufacturing a photovoltaic cell according to claim 1, wherein the single visible-light absorbing layer is applied to the front sheet before assembly of the photovoltaic module.

19. The method according to claim 18, wherein the single visible-light absorbing layer is applied using one of the following application techniques: ink-jet printing, screen printing/stencilling, roller printing, tampon printing, pad printing, powder coating, laser sintering, thermal printing.
